(19) United States
(12) Patent Application Publication
(10) Pub. No.: US 2005/0067702 A1
(43) Pub. Date: Mar. 31, 2005

(54) Plasma surface modification and passivation of organo-silicate glass films for improved hardmask adhesion and optimal RIE processing

(75) Inventors: William G. America, Kingston, NY (US); Timothy J. Dalton, Ridgefield, CT (US); Kaushik A. Kumar, Beacon, NY (US); Heidi L. Wickland, Poughkeepsie, NY (US)

Correspondence Address: SCULLY SCOTT MURPHY & PRESSER, PC, 400 GARDEN CITY PLAZA, GARDEN CITY, NY, 11530, US

(73) Assignee: INTERNATIONAL BUSINESS MACHINES CORPORATION, ARMONK, NY (US)

(21) Appl. No.: 10/674,646

(22) Filed: Sep. 30, 2003

(51) Int. Cl. H01L 21/4763; H01L 23/02; H01L 29/40

(52) U.S. Cl. 257/753; 257/759; 438/623; 438/781

(57) ABSTRACT

Interconnect structure having enhanced adhesion between the various interfaces encompassing an organo-silicate glass (OSG) film, for use in semiconductor devices is provided herein. The novel interconnect structure includes a non-damaged plasma-treated low-k OSG surface to enhance the adhesion of the hardmask material to the OSG surface, and an unique deposition scheme for the hardmasks in order to make the entire structure pliant towards implementing mild processing condition during the reactive ion etch patterning of the dielectric structure in a damascene and dual-damascene scheme. The methods for making a semiconductor device having an enhanced adhesion and micromasks free profiles are also provided.

### FIELD OF THE INVENTION

The present invention generally relates to integrated circuits (ICs), and more particularly to interconnect structures, including, for example, multilevel interconnect structures, in which the adhesion of a hardmask to an underlying dielectric film is significantly improved by employing a novel plasma treatment process. The present invention is also directed to a method of fabricating an interconnect structure using a hardmask stack that has significantly improved adhesion with the underlying dielectric film, while enabling gentler reactive ion etch (RIE) patterning conditions.

### BACKGROUND OF THE INVENTION

Generally, semiconductor devices include a plurality of circuits which form an integrated circuit including chips (e.g., chip back end of line, or “BEOL”), thin film packages and printed circuit boards. Integrated circuits can be useful for computers and electronic equipment and can contain millions of transistors and other circuit elements that are fabricated on a single silicon crystal substrate. For the device to be functional, a complex network of signal paths will normally be routed to connect the circuit elements distributed on the surface of the device.

Efficient routing of these signals across the device can become more difficult as the complexity and number of the integrated circuits is increased. Thus, the formation of multi-level or multi-layered interconnection schemes such as, for example, dual damascene wiring structures, have become more desirable due to their efficacy in providing high speed signal routing patterns between large numbers of transistors on a complex semiconductor chip. Within a typical interconnected structure, metal vias run perpendicular to the silicon substrate and metal lines run parallel to the silicon substrate.

Broadly, there are two limiting factors that affect the speed of signal propagation in BEOL interconnects, namely, the resistance (R) of the wire and the capacitance (C) of the insulation between (also referred to as inter-layer-dielectric) the current carrying metal wires. The combination of these two factors manifests itself as interconnect or RC delay. One of the key challenges in the interconnect technologies is to reduce the electrical signal delay. This can be achieved by novel material changes, such as by replacing the traditionally used silicon-dioxide films with low dielectric constant (k) materials.

Porous-Organo-Silicate Glass (pOSG) films, with a dielectric constant, k, value lower than 3.0, are being presently investigated as a potential candidate insulation material for thin-wire integration.

In the integration of pOSG films, several dielectric films are deposited atop the pOSG film in order to serve as hardmasks, which are used in the fabrication of the trenches and vias. In order to fabricate a robust structure, the adhesion of the hardmasks with each other and to the pOSG films is critical. One common prior art technique that is employed to enhance the adhesion between two films is by plasma-treatment of the underlying film prior to the deposition of the subsequent film. Typically, a plasma treatment process roughens the underlying film at microscopic dimensions, and hence increases the surface area for nucleation and/or adhesion of the subsequent deposited film. However, in the case of pOSG films, the open porosity on the surface of this film offers an increased surface area for the nucleation of the hardmask film. The adhesion, however, is marginal and does not survive subsequent integration steps. Hence, plasma treatment, by means of which a surface modification is achieved, is necessary to enhance the adhesion of the hardmasks to the pOSG film.

Another problem associated in the fabrication of robust structures using pOSG films lies in the identification of appropriate hardmask films. These hardmask films serve multiple purposes, such as, for example, a chemical-mechanical polishing (CMP) stop layer, an oxygen diffusion barrier layer, and etc. Typical films that are used as hardmask include silicon carbides (SiC) and related films of similar structure, such as hydrogenated-SiC and nitrogenated-SiC. These films serve as robust CMP-stop layers and also are good oxygen barriers. However, in order to maintain the oxygen barrier properties, the surface of the SiC film needs to be densified after deposition.

The densified SiC film serves as a hermitically sealed surface prior to the deposition of the subsequent film. The densified SiC film is not uniform, with respect to film thickness and composition, across the wafer and also within the thickness of the altered surface. The non-uniformity in the densified SiC film creates an extremely rough interface for the subsequent reactive-ion-etch (RIE) patterning. This results in micromasking during the RIE processing which can cause formation of an undesirable final structure. Moreover, micromasked structures can lead to premature device reliability failures. The presence of the densified layers within the hardmask or the hardmask-pOSG film interface can be addressed by using aggressive RIE process conditions. However, this is detrimental towards the pOSG films that cannot withstand aggressive RIE conditions.

It would therefore be desirable to provide an interconnect structure that can provide robust adhesion at the interface of the hardmask and pOSG film without changing the bulk of the pOSG film. This allows for the integration of pOSG in an interconnect structure. It would also be desirable for the hardmask stack to possess no intermediate densified layers that could lead to micromasked structures in the final interconnect structure. The absence of densified layers, within the hardmasks and at the hardmask-pOSG film interface, enhances the RIE process window and allows for gentler RIE conditions.

### SUMMARY OF THE INVENTION

It is therefore an object of the present invention to provide a film structure which includes at least an OSG film (porous, non-porous or a combination of porous and non-porous), that would enable the fabrication of a BEOL interconnect structure of, e.g., the single damascene and dual damascene type.

It is also an object of the present invention to provide a BEOL interconnect structure with robust adhesion between the OSG surface and a hardmask.

It is also an object of the present invention to provide a BEOL interconnect structure with improved adhesion between hardmask films while eliminating buried densified layers. As stated above, such densified layers often result in severe micromasking effects during the RIE patterning of the interconnect structure.

These and other objects are achieved in the present invention by providing a method for fabricating a unique structure using OSG (porous, non-porous or a combination of porous and non-porous) and appropriate hardmasks. The method of the present invention ensures robust adhesion of the hardmask material to the OSG by using a new plasma treatment process to change the surface morphology of the pOSG film. The plasma treatment employed in the present invention does not damage the OSG film during the plasma treatment, yet it is capable of tailoring the interfaces between the sacrificial interfaces such that micromasking is eliminated during RIE processes.

Specifically, the present invention provides a method for making an interconnect structure including an OSG dielectric material having substantially enhanced adhesion and minimal micromasking which comprises the following steps:

surface modification of the morphology of the OSG film through a non-damaging plasma treatment process, the main role of which is to chemically activate the surface of the OSG film;

deposit, in-situ or ex-situ, an appropriate hardmask, such as, for example, SiC, SiCH, SiCN, SiCHN, SiCOH, that serves as a hermetically sealed dielectric film;

optionally, deposit, in-situ or ex-situ, another dielectric hardmask stack, unitary or hybrid, in order to protect the first hardmask and the patterning photoresist from each other, without changing the surface of the first hardmask dielectric film,

eliminate all buried densified layers in the hardmask stack.

The above processing steps may be repeating any number of times to provide a multilayered structure.

### BRIEF DESCRIPTION OF THE DRAWINGS

The features of the present invention are believed to be novel, and the elements characteristics of the invention are set forth in the appended claims. The figures are for illustration purposes and are not drawn to scale. The preferred embodiments of the present disclosure are described below with reference to the drawings, which are described as follows:

FIG. 1 is a schematic cross-sectional view of an interconnect structure of the present invention with a densified layer within the hardmask stack;

FIG. 2 is a schematic cross-sectional view of the interconnect structure of FIG. 1 showing the effect of micromasking, during the RIE patterning of the dielectric structure;

FIG. 3 is a schematic cross-sectional view of an alternative embodiment of the interconnect structure of FIG. 1, showing the desired smooth etch front required in the patterning of the interconnect structure.

### DETAILED DESCRIPTION OF THE INVENTION

The present invention is directed to an interconnect structure useful for forming a semiconductor device, the interconnect structure having a low-k OSG dielectric layer, and an associated low-k hardmask dielectric stack. Enhanced adhesion between the OSG dielectric film and the hardmask dielectric stack is achieved by means of a mild plasma surface treatment of the OSG film surface. Typically, it has been observed and reported widely in the literature that plasma treatment of OSG films leads to an overall increase of the dielectric constant indicating damage to at least a surface layer of the OSG material. This damaged surface layer causes an increase in the capacitance and leakage within the dielectric material when subjected to an electrical stress, which leads to reliability failure of the interconnect structure.

The interconnect structure of the present invention is based on the surprising discovery that particular plasma conditions used to enhance the adhesion of the dielectric material to the hardmask dielectric material, did not cause a substantial increase in the dielectric constant of the OSG film or result in leakage in the structure. Hence, no substantial damaged surface layer is formed into the OSG film using the plasma conditions described herein. Instead, the plasma treatment process of the present invention provides a substantially non-damaged surface layer that is chemically activated for providing improved adhesion to an overlying hardmask. Additionally, it was also discovered that removing all the densified layers within the hardmask stack resulted in micromasking-free structures, while maintaining the integrity of the hardmask dielectric stack. The interconnect structure of the present invention will now be described in more detail by referring to the drawings that accompany the present application.

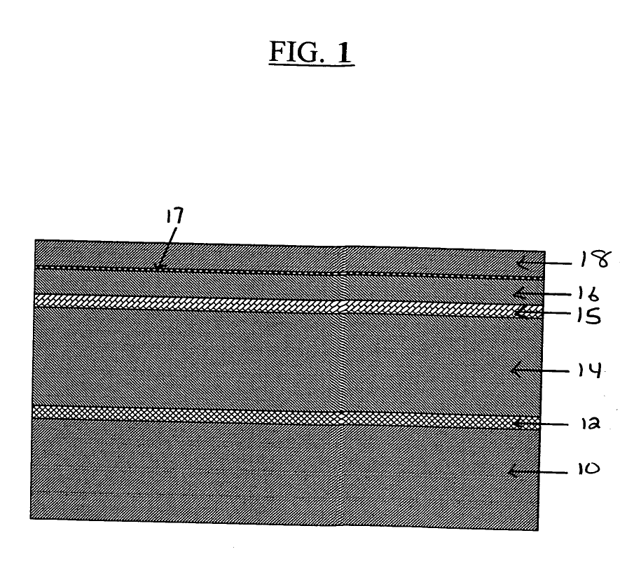

Referring now to FIG. 1, one such semiconductor device in accordance with the present invention can be formed by first providing an integrated circuit structure 10 which is formed in a semiconductor material substrate. The expression “integrated circuit structure” as used herein refers to, for example, an integrated circuit at the end of its formation as is known in the art, i.e., after formation of metallization strips.

The substrate may be a semiconductor wafer or chip that is composed of any silicon-containing semiconductor material such as, for example, Si, SiGe, Si/SiGe, Si/SiO₂/Si, etc. The substrate may be of the n- or p-type depending on the desired device to be fabricated. Moreover, the substrate may contain various isolation and/or device regions either formed in the substrate or on a surface thereof. The substrate may also contain metallic pads on the surface thereof. In addition to silicon-containing semiconductor materials, the substrate may also be a circuit that includes complementary metal oxide semiconductor (CMOS) devices therein.

Referring again to FIG. 1, a dielectric material 12, herewith referred to as the cap layer, is deposited on top of the integrated circuit 10 in order to serve as a protection layer by encapsulating the underlying integrated circuit 10. The main role of the dielectric material, i.e., cap layer, 12 is to protect the underlying integrated circuit 10 from oxidants, moisture, and ionic contamination. Depending on the nature of the material and its effectiveness in performing as a diffusion barrier, the thickness of the dielectric cap layer 12 can vary from a couple of nanometers to few-tens of nanometers. The dielectric cap layer 12 can be comprised of any suitable capping material, such as, for example, silicon nitride, silicon carbide, silicon oxycarbide, hydrogenated silicon carbide, silicon dioxide, organosilicate glass, and other low-k dielectric materials. The dielectric cap layer 12 can also be used as an etch stop during the patterning of ILD (inter-level dielectric) 14.

Dielectric cap layer 12 can be formed using a conventional deposition process including, for example, chemical vapor deposition (CVD), plasma enhanced chemical vapor deposition (PECVD), evaporation, spin on coating, atomic layer deposition, chemical solution deposition and other like deposition processes.

In some embodiments, dielectric cap layer 12 is comprised of a dielectric material comprising Si, C, N and H; C and/or N are optional. In such an embodiment, the dielectric cap 12 comprises 10 to about 40 at. % Si, about 0 to about 30 at. % C, about 0 to about 30 at. % N and about 20 to about 50 at. % H. In the foregoing sentence and in the remaining text, the abbreviation “at.” denotes “atomic”.

The dielectric cap layer 12 encapsulates the finished metallization layer of IC 10. In embodiments in which Cu is employed as the metallization layer, the dielectric cap layer 12 serves as a diffusion barrier that prevents Cu with interacting with the ILD layer. The dielectric cap layer 12 also prevents the interaction of oxidants with the metallization layer.

In accordance with the present invention, an organo-silicate glass (OSG) material is then formed atop the dielectric cap layer 12. The OSG material forms the ILD (i.e., interlayer dielectric)14 of the structure. The terms “ILD” or “OSG” or “pOSG” are used interchangeably throughout the instant application to denote layer 14 of the inventive structure. Any OSG dielectric material may be employed as the ILD 14. In particular, the OSG dielectric includes a material with a dielectric constant value of less than 3. The OSG dielectric material may be non-porous, porous or it may comprise a combination of porous and non-porous OSG materials. Preferably, the OSG material is a porous material having a porosity of about 70% or less. The average pore size and size distribution of the materials used for the ILD 14 will ordinarily range from about 1 to about 25 nm, with less than about 5 nm being preferred.

In one embodiment of the present invention, the OSG material comprises a material including Si, C, O and H that has a dielectric constant of less than 3. In this embodiment, the OSG material preferably comprises about 10 to about 40 at. % Si, about 10 to about 40 at. % C, about 15 to about 45 at. % O and about 20 to about 50 at. % H.

The ILD 14 is formed utilizing a conventional deposition process including, for example, CVD, PECVD, spin on coating, evaporation and other like deposition process. When pores are present, a porogen may be included in the precursor material and it is removed after deposition using techniques well known in the art. Deposition may occur in-situ or ex-situ on the dielectric cap 12.

As commonly known by those skilled in the art, one of the major problems with the integration of the OSG materials as an ILD layer, is the poor adhesion with an overlying hardmask dielectric material 16, herewith referred to as lower hardmask. The lower hardmask 16 serves multiple purposes, as known to those skilled in the art, such as a chemical-mechanical polish (CMP) stopping layer, a barrier to protect the OSG material, i.e., the ILD 14, from moisture and slurry solvents, and a template to enable the patterning of the OSG material, i.e., the ILD 14. The lower hardmask 16 can be comprised of any suitable dielectric material, such as silicon nitride, silicon carbide, silicon oxycarbide, hydrogenated silicon carbide, silicon dioxide, organosilicate glass, and other low-k dielectric materials.

The lower hardmask 16 is formed utilizing one of the above-mentioned deposition process used in forming the dielectric cap layer 12. The deposition may occur in-situ or ex-situ. The thickness of lower hardmask 16 may vary depending on the specific dielectric material and the technique used in forming the same. The lower hardmask 16 should however by sufficiently thick to provide the various functions mentioned above.

In one embodiment, the lower hardmask 16 comprises an inorganic material including Si, C, H and optionally O and/or N. In such an embodiment, the lower hardmask 16 may comprise about 10 to about 40 at. % Si, about 10 to about 40 at. % C, about 0 to about 45 at. % O, and about 25 to about 55 at. % H. In yet other embodiment, the lower hardmask 16 comprises 10 to about 40 at. Si, about 10 to about 40 at. % C, about 0 to about 45 at. % O, about 25 to about 55 at. % H and about 5 to about 25 at. % N. The dielectric constant of such lower hardmasks 16 is less than 5.

One commonly known method, which has been historically used to improve the adhesion between two smooth interfaces is to roughen the interfaces. This roughening increases the surface area available to promote the adhesion of the two surfaces. Another prior technique to improve adhesion, is to chemically modify the surface of one of the films by creating reactable dangling bonds that are used to chemically link or bond to the second film. One method of achieving the latter objective in thin-film technology is to plasma-treat the ILD film surface.

pOSG ILDs, due to the high degree of porosity, offer a rough surface at the nanometer scale. The adhesion of the pOSG dielectric, i.e., the ILD 14, to the lower hardmask 16, in spite of the ILD's rough texture and high surface area, is poor. Thus, plasma treatment becomes necessary to create reactable dangling bonds on the surface of the pOSG film (i.e., the ILD 14) in order to promote the bonding of the lower hardmask 16. This is shown as a separate layer in FIG. 1 as layer 15, herewith referred to as plasma altered OSG layer. A requirement of the plasma treatment process of the present invention, which is different from prior art approaches, is that the OSG dielectric (i.e., the ILD 14) is not damaged by the plasma process. This limits the choice of appropriate plasma conditions in terms of the plasma gas, operating power and the duration of exposure.

In one prior art, plasma approach developed by SEMATECH, exposure of an OSG dielectric for 0.5 sec. six-times at a plasma power of 1000 W enabled the adhesion of the hardmask material to the underlying OSG layer. However, there are two drawbacks in this prior art approach, i.e., the instability of plasma conditions in 0.5 sec. duration and the damage to the OSG film due to the high power density. The plasma altered OSG surface layer 15, under the SEMATECH condition, raises the effective dielectric constant of the OSG film and negates the introduction of a lower-k dielectric material.

Investigation of the plasma conditions was undertaken by the applicants of the present invention, where the choice of gas was limited to light gases such as, hydrogen (H₂), helium (He) and nitrogen (N₂), the plasma power was varied from 100 W to 250 W and the duration was varied from 1 sec. to 30 secs. From these investigations, it was determined that more damage was caused, in terms of dielectric constant of the OSG film, when heavier gases such as nitrogen were used or when the duration of plasma exposure was too long. The net increase in the dielectric constant of the OSG with the altered plasma treated surface layer was greater than 10%. This was expected due to the damaging nature of those plasma conditions.

The surprising finding of the above study conducted by the applicants, that forms the core of this invention, is the existence of a process window for the plasma conditions which resulted in greater than 15% improvement in the adhesion of the lower hardmask 16 without any measurable change in the dielectric constant of the ILD 14. The plasma conditions used in the present invention include the use of H₂ or He, preferably H₂, as the gas, limiting the plasma power to less than about 200 W and plasma exposure to less than about 10 sec. These conditions proved to be very useful in modifying the morphology of the surface of the OSG film (i.e., the ILD 14) to enable adhesion to the lower hardmask 16 without chemically changing the bulk of the OSG material (i.e., the ILD 14). That is, the plasma conditions employed in the present invention do not substantially damage the surface layer 15 of the ILD 14. The plasma treatment process of the present invention also does not alter the electrical characteristics or the dielectric constant of the ILD 14. Typically, the variation in dielectric constant caused by the plasma treatment process of the present invention is less than 0.05.

In addition to the above-mentioned processing conditions, the plasma process of the present invention is carried at an operating pressure of from about 0.1 Torr to about 10 Torr.

Additionally, it was also observed that keeping the interface clean after the plasma treatment lent itself to better adhesion conditions to the lower hardmask 16, and hence this imposed that the lower hardmask 16 be deposited in-situ after the plasma-altering of the OSG surface. Although an in-situ deposition is preferred, the lower hardmask 16 may be formed ex-situ as well.

Keeping in view of the fact that the lower hardmask 16 is retained after CMP, it is preferably advantageous to have a low-k material as the hardmask dielectric material so as to keep the effective dielectric constant of the entire stack low. The major drawback of this requirement is that the materials that satisfy this condition are susceptible to photoresist rework conditions that typically involve oxygen-based or nitrogen-based plasma strip conditions. Hence, in order to protect low-k hardmask dielectric materials from damaging photoresist strip conditions, another protective hardmask dielectric layer 18, herewith referred to as upper hardmask, is deposited on lower hardmask 16. The upper hardmask 18, depending on the integration scheme, could be a single material or a hybrid material. The upper hardmask 18 can comprise any suitable material that withstands photoresist rework conditions, such as, for example, silicon nitride, silicon dioxide, silicon oxy-nitride, tantalum nitride, and titanium nitride. As can be appreciated by those skilled in the art, these materials are either high-k or metallic, and hence should be completely sacrificial, i.e., should be completely removed after CMP in order to preserve the integrity of the structure.

Typically, an ex-situ deposition of the upper hardmask 18 involves the use of a reactive plasma clean step prior to the deposition of the hardmask material that would damage the bulk of the low-k lower hardmask 16. In order to prevent this damage, the surface of the lower hardmask 16 is often densified in inert-gas plasma, such as He plasma. This is shown in FIG. 1 as a separate layer 17, herewith referred to as the plasma densified layer. Analogous to the OSG plasma altered layer 15, layer 17 may also be used to promote adhesion within the hardmask layers. As stated earlier, the advantage of densified surface layer 17 is that it readily encourages ex-situ deposition of the upper hardmask 18.

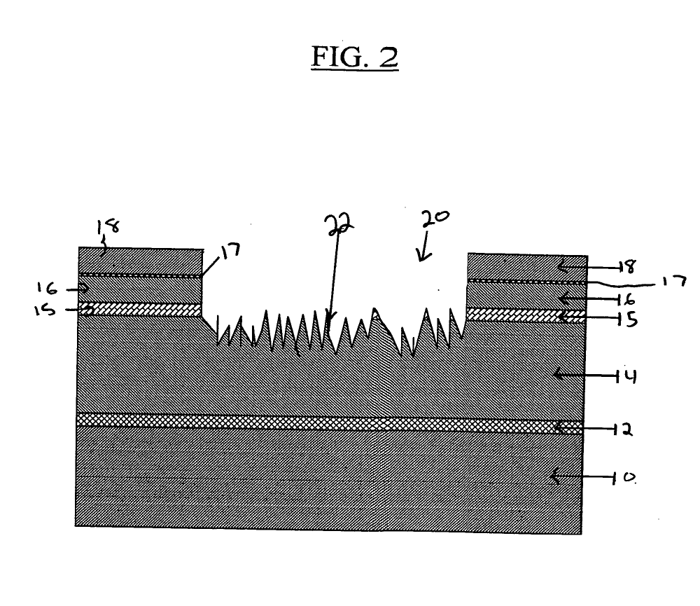

FIG. 1 shows a structure that has at least two modified layers, i.e., layers 15 and 17. One of the major issues in fabricating such structures is that these layers may adversely influencing the patterning process. Modified layers 15 and 17 are spatially non-uniform in composition and morphology and pose a serious challenge in reactive ion etch (RIE) patterning of the OSG structure as shown in FIG. 2 as 20. As can be appreciated by those skilled in the art, a gradation in the composition of a material could significantly change the etch rate of the material during RIE. So a non-uniform lateral and spatial composition of the densified films locally alters the etch rate of the material. The non-uniformity results in a micromasked profile as shown in FIG. 2 as 22, herewith referred to as micromasks.

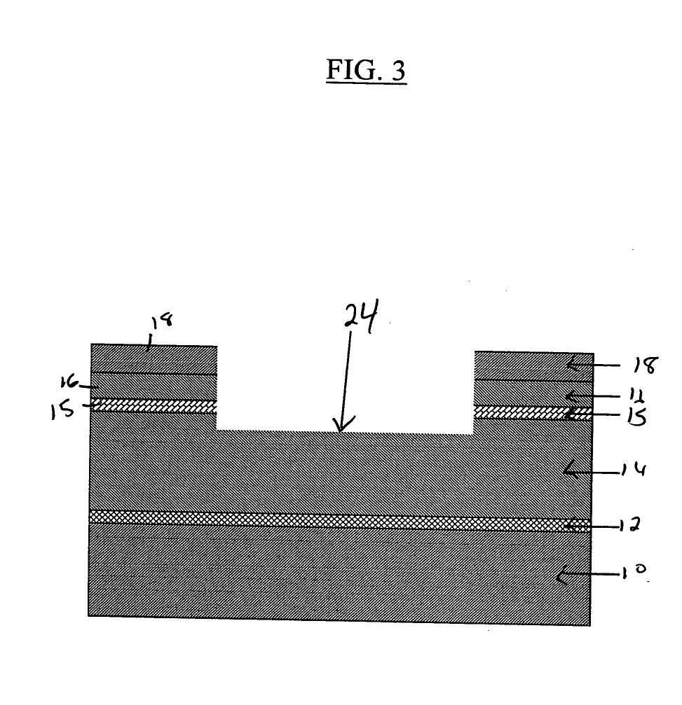

An embodiment of this invention relates to maintaining the requirements posed by deposition of hardmask films, while trying to attain a smooth etch front without the occurrence of micromasks. In the case of the deposition of the hardmasks, it was found that eliminating the plasma densified layer 17 (FIG. 2) leads to a dramatic reduction of micromasks. This, however, poses a problem, wherein deposition of the upper level hardmasks could not be achieved without damaging the lower surface through plasma cleaning of the lower hardmask. This problem was immediately alleviated by depositing the upper level hardmask 18 in-situ on the lower level hardmask 16. The surprising discovery of this study resulted in the find that the hardmask survived CMP processes up to a pad down-force of 5 psi, whereas, it was expected that the adhesion would be very weak. Taking the film stack through RIE, by eliminating layer 17, resulted in smooth etch fronts in OSG, i.e., the ILD 14. This result is shown in layer 24 in FIG. 3.

Another embodiment of this invention involves the plasma altered layer 15, which did not influence the etch front in the OSG film (i.e., ILD 14). This suggests, that the plasma conditions used in improving the adhesion of the lower hardmask 16 to the OSG film 14, did not alter the morphology and microstructure beyond the surface of the OSG film 15 to an extent where it caused micromasking effects, while still modifying the surface to improve adhesion.

Hence, this invention includes a method of building a structure, encompassing an OSG dielectric material, wherein, the surface of OSG was altered to increase adhesion to the hardmask material without affecting the RIE patterning process, and a method of depositing the relevant hardmasks, in-situ, without forming intermediate densified layers that cause micromasked profiles. Although the invention has been described in its preferred form with a certain degree of particularity, obviously many changes and variations are possible therein and will be apparent to those skilled in the art after reading the foregoing description. For example, additional layers known in the art can be formed on the top of the upper hardmask 18.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

1. An interconnect structure comprising:
one or more interconnect levels, one on top of each other, each level comprising a organo-silicate glass (OSG) dielectric material having a plasma treated surface layer that provides improved adhesion to an overlying lower hardmask, yet is substantially undamaged.

2. The interconnect structure of claim 1 wherein the OSG dielectric material comprises a non-porous or porous material having a dielectric constant less than 3.

3. The interconnect structure of claim 1 wherein the OSG dielectric material comprises a combination of porous and non-porous OSG materials.

4. The interconnect structure of claim 1 wherein the OSG dielectric material comprises a material of Si, C, O and H and having a dielectric constant less than about 3.

5. The interconnect structure of claim 4 wherein the OSG dielectric material comprises about 10 to about 40 atomic (at.) % Si, about 10 to about 40 at. % C, about 15 to about 45 at. % O, and about 20 to about 50 at. % H.

6. The interconnect structure of claim 1 further comprising a dielectric cap layer beneath said OSG dielectric material.

7. The interconnect structure of claim 1 wherein the lower hardmask comprises a dielectric material of Si, C, O and H and having a dielectric constant less than about 5.

8. The interconnect structure of claim 1 wherein the lower hardmask comprises of a dielectric material of Si, C, O, H and N and having a dielectric constant less than about 5.

9. The interconnect structure of claim 1 wherein the adhesion improved by greater than 15%.

10. The interconnect structure of claim 1 further comprising an upper hardmask located atop said lower hardmask.

11. The interconnect structure of claim 10 wherein said lower hardmask does not include a densified surface layer.

12. A method of forming an interconnect structure comprising:
plasma treating an OSG dielectric layer to provide a plasma-treated OSG surface layer that provides improved adhesion to an overlying lower hardmask, said plasma-treated OSG surface layer is chemically and electrical unaltered from the bulk of the OSG dielectric layer; and
forming said lower hardmask atop the plasma-treated OSG surface layer.

13. The method of claim 12 wherein the plasma treatment is performed in H₂ or He, at a plasma power of less than about 200 W and a plasma exposure of less than about 10 sec.

14. The method of claim 12 wherein the plasma treating causes a variation in the dielectric constant of the OSG dielectric of less than 0.05.

15. The method of claim 12 wherein the lower hardmask is formed in-situ.

16. The method of claim 12 further comprising forming an upper hardmask atop the lower hardmask.

17. The method of claim 16 wherein the upper hardmask is formed in-situ thereby avoiding the need for densifying the lower hardmask prior to upper hardmask deposition.

18. The method of claim 17 wherein the absence of densifying leads to a reduction in micromask formation during a subsequent reactive ion etch step.

19. A method of forming an interconnect structure comprising:
providing an integrated circuit that includes a dielectric cap layer located thereon;
forming an organo-silicate glass (OSG) dielectric layer on said dielectric cap layer; and
plasma treating the OSG dielectric layer to provide a plasma-treated OSG surface layer that provides improved adhesion to an overlying lower hardmask, said plasma-treated OSG surface layer is chemically and electrical unaltered from the bulk of the OSG dielectric layer;
in-situ forming said lower hardmask atop the plasma-treated OSG surface layer; and
in-situ forming an upper hardmask atop said lower hardmask.
